(19) United States
(12) Patent Application Publication
(10) Pub. No.: US 2025/0301636 A1
(43) Pub. Date: Sep. 25, 2025

(54) MICROELECTRONIC DEVICES, AND RELATED MEMORY DEVICES AND ELECTRONIC SYSTEMS

(71) Applicant: Micron Technology, Inc., Boise, ID (US)

(72) Inventors: Fatma Arzum Simsek-Ege, Boise, ID (US); Yadhu Vamshi Sindhoor Reddy Vancha, Meridian, ID (US); Beau D. Barry, Boise, ID (US)

(21) Appl. No.: 19/060,405

(22) Filed: Feb. 21, 2025

Related U.S. Application Data
(60) Provisional application No. 63/569,067, filed on Mar. 22, 2024.

(51) Int. Cl. H10B 12/00; G11C 11/408; G11C 11/4091; H01L 23/00; H01L 25/065; H01L 25/18; H10B 80/00

(52) U.S. Cl. CPC H10B 12/50; H01L 24/08; H01L 25/0657; H01L 25/18; H10B 12/315; H10B 80/00; G11C 11/4085; G11C 11/4091; H01L 2224/08145; H01L 2924/1431; H01L 2924/1436

(57) ABSTRACT

A microelectronic device includes a control circuitry structure and a memory array structure bonded to the control circuitry structure. The control circuitry structure includes a control circuitry region including two sense amplifier (SA) sub-regions including SA circuitry, and two sub-word line driver (SWD) sub-regions including SWD circuitry. The two SA sub-regions horizontally extend between opposing boundaries of the control circuitry region in a first direction. The two SWD sub-regions are interposed between the two SA sub-regions in a second direction and individually include a central region adjacent a respective one of the opposing horizontal boundaries of the control circuitry region, and two arm regions at opposing ends of the central region in the second direction and respectively horizontally protruding, in the first direction, from the central region. The memory array structure includes an array region horizontally overlapping the control circuitry region of the control circuitry structure and including memory cells.

### CROSS-REFERENCE TO RELATED APPLICATIONS

This application claims the benefit under 35 U.S.C. § 119(e) of U.S. Provisional Patent Application Ser. No. 63/569,067, filed Mar. 22, 2024, the disclosure of which is hereby incorporated herein in its entirety by this reference.

### TECHNICAL FIELD

The disclosure, in various embodiments, relates generally to the field of microelectronic device design and fabrication. More specifically, the disclosure relates to microelectronic devices, and to related memory devices, electronic systems, and methods.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified, easier and less expensive to fabricate designs.

One example of a microelectronic device is a memory device. Memory devices are generally provided as internal integrated circuits in computers or other electronic devices. There are many types of memory devices including, but not limited to, volatile memory devices. One type of volatile memory device is a dynamic random-access memory (DRAM) device, A DRAM device may include a memory array including DRAM cells arranged rows extending in a first horizontal direction and columns extending in a second horizontal direction. In one design configuration, an individual DRAM cell includes an access device (e.g., a transistor) and a storage node device (e.g., a capacitor) electrically connected to the access device. The DRAM cells of a DRAM device are electrically accessible through digit lines and word lines arranged along the rows and columns of the memory array and in electrical communication with control logic devices within a base control logic structure of the DRAM device.

Control logic devices within a base control logic structure underlying a memory array of a DRAM device have been used to control operations on the DRAM cells of the DRAM device. Control logic devices of the base control logic structure can be provided in electrical communication with digit lines and word lines coupled to the DRAM cells by way of routing and contact structures. Unfortunately, processing conditions (e.g., temperatures, pressures, materials) for the formation of the memory array over the base control logic structure can limit the configurations and performance of the control logic devices within the base control logic structure. In addition, the quantities, dimensions, and arrangements of the different control logic devices employed within the base control logic structure can also undesirably impede reductions to the size (e.g., horizontal footprint) of a memory device, and/or improvements in the performance (e.g., faster memory cell ON/OFF speed, lower threshold switching voltage requirements, faster data transfer rates, lower power consumption) of the DRAM device.

### BRIEF DESCRIPTION OF THE DRAWINGS

FIG. 1 is a simplified, partial vertical cross-sectional view of a microelectronic device, in accordance with embodiments of the disclosure.

FIG. 2 is a simplified, partial schematic view of a memory array structure for the microelectronic device depicted in FIG. 1, in accordance with some embodiments of the disclosure.

FIG. 3 is a simplified, partial schematic view of a control circuitry structure for the microelectronic device depicted in FIG. 1, in accordance with some embodiments of the disclosure.

FIG. 4 is a diagram showing different vertical cross-sectional views of the microelectronic device collectively shown in FIGS. 1-3, taken about lines A-A and B-B depicted in FIGS. 2 and 3.

FIGS. 5 through 7 are simplified, partial top-down views of the microelectronic device collectively shown in FIGS. 1 through 4, taken about dashed box C shown in FIG. 3, showing different feature configurations within a portion of the microelectronic device, in accordance with some embodiments of the disclosure.

FIG. 8 is a schematic block diagram of an electronic system, in accordance with an embodiment of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional volatile memory; conventional non-volatile memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric oxycarbide material (e.g., silicon oxycarbide (SiOₓC_{y})), at least one hydrogenated dielectric oxycarbide material (e.g., hydrogenated silicon oxycarbide (SiCO_{y}H_{z})), and at least one dielectric carboxynitride material (e.g., a silicon carboxynitride (SiOₓC_{z}N_{y})). In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., AlₓGa_{1-X}As), and quaternary compound semiconductor materials (e.g., GaₓIn_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials. In addition, each of a “semiconductor structure” and a “semiconductive structure” means and includes a structure formed of and including semiconductor material.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

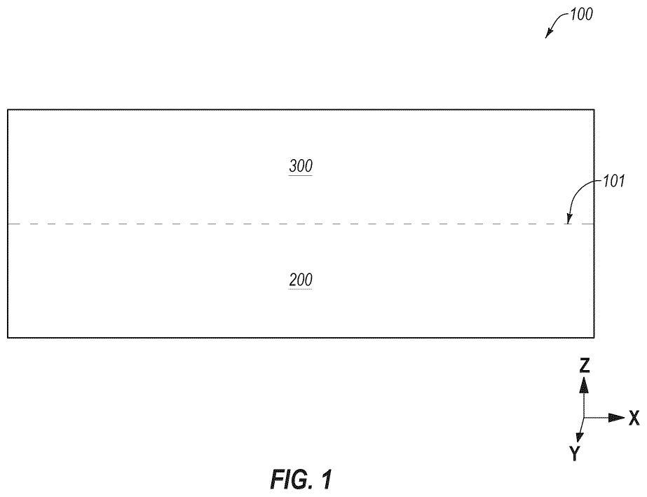

FIG. 1 is a simplified, partial vertical cross-sectional view of a microelectronic device 100 (e.g., a memory device, such as a DRAM device), in accordance with some embodiments of the disclosure. The microelectronic device 100 may include a memory array structure 200 (e.g., a memory array wafer), and a control circuitry structure 300 (e.g., a control circuitry wafer) vertically overlying and attached to the memory array structure 200. The memory array structure 200 may include one or more array(s) of memory cells (e.g., volatile memory cells, such as DRAM cells). At least a majority (e.g., substantially all) of the memory cells of the microelectronic device 100 may be located within the memory array structure 200 (and, hence, outside of the control circuitry structure 300). The control circuitry structure 300 may include control logic devices formed of and including complementary metal-oxide-semiconductor (CMOS) circuitry. At least a majority (e.g., substantially all) of the CMOS circuitry (and, hence, the control logic devices) of the microelectronic device 100 may be located within the control circuitry structure 300 (and, hence, outside of the memory array structure 200). In addition, at least some of the CMOS circuitry may be positioned vertically above within horizontal areas of the array(s) of memory cells. Accordingly, the microelectronic device 100 may be considered to have a so-called “CMOS above array (CaA)” configuration.

In some embodiments, the control circuitry structure 300 is formed, at least in part, separate from the memory array structure 200; and then the control circuitry structure 300 is attached (e.g., bonded) to the memory array structure 200 at an interface 101 using dielectric-dielectric (e.g., oxide-oxide) bonding or a combination of dielectric-dielectric bonding and metal-metal bonding. For example, following the separate formations of the memory array structure 200 and the control circuitry structure 300, the control circuitry structure 300 and the memory array structure 200 may be brought into physical contact with one another at the interface 101, and then the resulting assembly may be exposed to a temperature greater than or equal to about 400° C. (e.g., within a range of from about 400° C. to about 800° C., greater than about 800° C.) to form oxide-to-oxide bonds between oxide dielectric material (e.g., SiOₓ, such as SiO₂) of the memory array structure 200 and additional oxide dielectric material (e.g., additional SiOₓ, such as additional SiO₂) of the control circuitry structure 300. In some embodiments, the oxide dielectric material of the memory array structure 200 and the additional oxide dielectric material of the control circuitry structure 300 are exposed to at least one temperature greater than about 800° C. to form oxide-to-oxide bonds between the oxide dielectric material of the memory array structure 200 and the additional oxide dielectric material of the control circuitry structure 300.

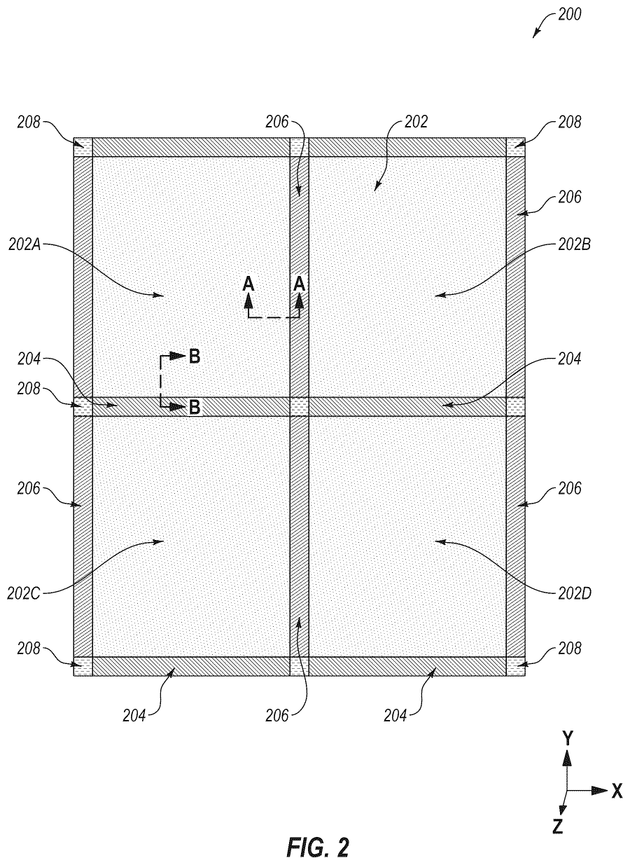

FIG. 2 is a simplified, partial schematic view of a portion of the memory array structure 200 of the microelectronic device 100 (FIG. 1), in accordance with some embodiments of the disclosure. FIG. 2 shows an arrangement of various circuitry of the memory array structure 200.

As shown in FIG. 2, the memory array structure 200 may include array regions 202, digit line exit regions 204 interposed between pairs of the array regions 202 horizontally neighboring one another in the Y-direction, word line exit regions 206 interposed between additional pairs of the array regions 202 horizontally neighboring one another in the X-direction orthogonal to the Y-direction, and minigap regions 208 interposed between neighboring pairs of the digit line exit regions 204 in the X-direction and neighboring pairs of the word line exit regions 206 in the Y-direction. The array regions 202, the digit line exit regions 204, the word line exit regions 206, and the minigap regions 208 of the memory array structure 200 are each described in further detail below.

The array regions 202 of the memory array structure 200 may be regions of the memory array structure 200 having arrays of memory cells (e.g., arrays of DRAM cells) within horizontal area thereof. The memory array structure 200 may be formed to include a desired quantity of the array regions 202. For clarity and ease of understanding of the drawings and related description, FIG. 2 depicts the memory array structure 200 as including four (4) array regions 202: a first array region 202A, a second array region 202B, a third array region 202C, and a fourth array region 202D. As shown in FIG. 2, the second array region 202B may horizontally neighbor the first array region 202A in the X-direction, and may horizontally neighbor the fourth array region 202D in the Y-direction; the third array region 202C may horizontally neighbor the first array region 202A in the Y-direction, and may horizontally neighbor the fourth array region 202D in the X-direction; and the fourth array region 202D may horizontally neighbor the third array region 202C in the X-direction, and may horizontally neighbor the second array region 202B in the Y-direction. However, the memory array structure 200 may include a different quantity of array regions 202. For example, the memory array structure 200 may be formed to include greater than four (4) array regions 202, such as greater than or equal to eight (8) array regions 202, greater than or equal to sixteen (16) array regions 202, greater than or equal to thirty-two (32) array regions 202, greater than or equal to sixty-four (64) array regions 202, greater than or equal to one hundred twenty eight (128) array regions 202, greater than or equal to two hundred fifty six (256) array regions 202, greater than or equal to five hundred twelve (512) array regions 202, or greater than or equal to one thousand twenty-four (1024) array regions 202.

As described in further detail below, the array regions 202 of the memory array structure 200 may individually include digit line structures (e.g., bit line structures, data line structures) extending the Y-direction, word line structures (e.g., access line structures) extending in the X-direction, and memory cells arranged at intersections of the digit line structures and the word line structures. Rows of the memory cells may be coupled to the word line structures, and columns of the memory cells may be coupled to the digit line structures. The memory cells within an individual array region 202 may, for example, comprise DRAM cells, resistive random-access memory (RRAM) cells, conductive bridge random-access memory (conductive bridge RAM) cells, magnetic random-access memory (MRAM) cells, phase change material (PCM) memory cells, phase change random-access memory (PCRAM) cells, spin-torque-transfer random-access memory (STTRAM) cells, oxygen vacancy-based memory cells, programmable conductor memory cells, or other types of memory cells. In some embodiments, the memory cells within an individual array region 202 of the memory array structure 200 are DRAM cells.

With continued reference to FIG. 2, the digit line exit regions 204 of the memory array structure 200 may comprise horizontal areas of the memory array structure 200 configured and positioned to have at least some of the digit line structures horizontally terminate therein. For an individual digit line exit region 204, at least some digit line structures operatively associated with the array regions 202 flanking (e.g., at opposing boundaries in the Y-direction) the digit line exit region 204 have ends within the horizontal boundaries of the digit line exit region 204. In addition, as described in further detail below, the digit line exit regions 204 may also be configured and positioned to include contact structures and routing structures within the horizontal boundaries thereof that are coupled to at least some of the digit line structures. Some of the contact structures within the digit line exit regions 204 may couple the digit line structures to control logic circuitry of control logic devices (e.g., sense amplifier (SA) devices, additional devices) within the control circuitry structure 300 (FIG. 1) of the microelectronic device 100 (FIG. 1). As shown in FIG. 2, in some embodiments, the digit line exit regions 204 horizontally extend in the X-direction, and are respectively horizontally interposed, in the Y-direction, between neighboring array regions 202. The digit line exit regions 204 may, for example, horizontally alternate with the array regions 202 in the Y-direction.

Still referring to FIG. 2, the word line exit regions 206 of the memory array structure 200 may comprise additional horizontal areas of the memory array structure 200 configured and positioned to have at least some of the word line structures horizontally terminate therein. For an individual word line exit region 206, at least some word line structures operatively associated with the array regions 202 flanking (e.g., at opposing boundaries in the X-direction) the word line exit region 206 have ends within the horizontal boundaries of the word line exit region 206. As described in further detail below, the word line exit regions 206 may also be configured and positioned to include contact structures and routing structures within the horizontal boundaries thereof that are coupled to the word line structures. Some of the contact structures within the word line exit regions 206 may couple the word line structures to control logic circuitry of additional control logic devices (e.g., sub-word line driver (SWD) devices, additional devices) within the control circuitry structure 300 (FIG. 1) of the microelectronic device 100 (FIG. 1). As shown in FIG. 2, in some embodiments, the word line exit regions 206 horizontally extend in the Y-direction, and are horizontally interposed, in the X-direction, between neighboring array regions 202. The word line exit regions 206 may, for example, horizontally alternate with the array regions 202 in the X-direction.

With continued reference to FIG. 2, the minigap regions 208 of the memory array structure 200 may comprise further horizontal areas of the memory array structure 200 including conductive contact structures and routing structures configured and positioned to facilitate electrical connections between one or more other features of the memory array structure 200 and/or the control circuitry structure 300 (FIG. 1). Some of the minigap regions 208 may individually be horizontally positioned between opposing corners of at least two (2) (e.g., two, four) of the array regions 202 horizontally neighboring one another. An individual minigap region 208 may be horizontally interposed, in the X-direction, between two (2) neighboring digit line exit regions 204; and may be substantially horizontally aligned, in the Y-direction, with each of the two (2) neighboring digit line exit regions 204. In addition, an individual minigap region 208 may be horizontally interposed, in the Y-direction, between two (2) neighboring word line exit regions 206; and may be substantially horizontally aligned, in the X-direction, with each of the two (2) neighboring word line exit regions 206. The minigap regions 208 of the memory array structure 200 may respectively be free of digit line structures and word line structures within a horizontal area thereof.

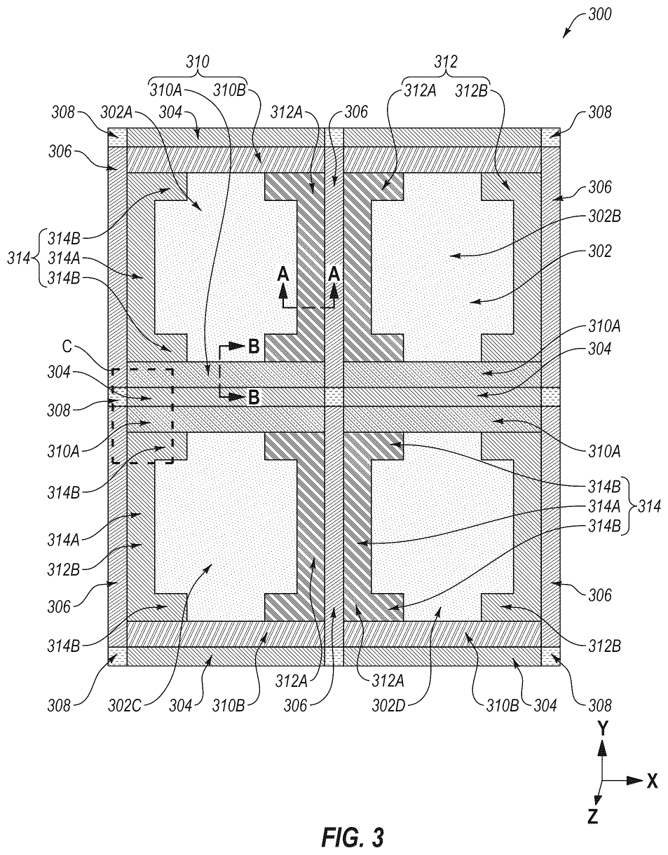

FIG. 3 is a simplified, partial schematic view of a portion of the control circuitry structure 300 of the microelectronic device 100 (FIG. 1), in accordance with some embodiments of the disclosure. FIG. 3 shows an arrangement of various circuitry of the control circuitry structure 300.

As shown in FIG. 3, the control circuitry structure 300 may include control circuitry regions 302, digit line contact regions 304 interposed between pairs of the control circuitry regions 302 horizontally neighboring one another in the Y-direction, word line contact regions 306 interposed between additional pairs of the control circuitry regions 302 horizontally neighboring one another in the X-direction orthogonal to the Y-direction, and additional minigap regions 308 interposed between neighboring pairs of the digit line contact regions 304 in the X-direction and neighboring pairs of the word line contact regions 306 in the Y-direction. The control circuitry regions 302, the digit line contact regions 304, the word line contact regions 306, and the additional minigap regions 308 of the control circuitry structure 300 are each described in further detail below.

The control circuitry regions 302 of the control circuitry structure 300 respectively include control logic circuitry of the control circuitry structure 300 within a horizontal area thereof. The control logic circuitry of the control circuitry regions 302 of the control circuitry structure 300 may be operatively associated with circuitry (e.g., memory cells) of the memory array structure 200 (FIG. 2), as described in further detail below. In some embodiments, the control circuitry regions 302 are individually configured to at least partially (e.g., substantially) horizontally overlap a respective array region 202 (FIG. 2) of the memory array structure 200 (FIG. 2).

The control circuitry structure 300 may be formed to include a desired quantity of the control circuitry regions 302. For clarity and ease of understanding of the drawings and related description, FIG. 3 depicts the control circuitry structure 300 as including four (4) control circuitry regions 302: a first control circuitry region 302A, a second control circuitry region 302B, a third control circuitry region 302C, and a fourth control circuitry region 302D. As shown in FIG. 3, the second control circuitry region 302B may horizontally neighbor the first control circuitry region 302A in the X-direction, and may horizontally neighbor the fourth control circuitry region 302D in the Y-direction; the third control circuitry region 302C may horizontally neighbor the first control circuitry region 302A in the Y-direction, and may horizontally neighbor the fourth control circuitry region 302D in the X-direction; and the fourth control circuitry region 302D may horizontally neighbor the third control circuitry region 302C in the X-direction, and may horizontally neighbor the second control circuitry region 302B in the Y-direction. The first control circuitry region 302A may at least partially (e.g., substantially) horizontally overlap the first array region 202A (FIG. 2) of the memory array structure 200 (FIG. 2); the second control circuitry region 302B may at least partially (e.g., substantially) horizontally overlap the second array region 202B of the memory array structure 200 (FIG. 2); the third control circuitry region 302C may at least partially (e.g., substantially) horizontally overlap the third array region 202C (FIG. 2) of the memory array structure 200 (FIG. 2); and the fourth control circuitry region 302D may at least partially (e.g., substantially) horizontally overlap the fourth array region 202D (FIG. 2) of the memory array structure 200 (FIG. 2). However, the control circuitry structure 300 may include a different quantity of control circuitry regions 302. For example, the control circuitry structure 300 may be formed to include greater than four (4) control circuitry regions 302, such as greater than or equal to eight (8) control circuitry regions 302, greater than or equal to sixteen (16) control circuitry regions 302, greater than or equal to thirty-two (32) control circuitry regions 302, greater than or equal to sixty-four (64) control circuitry regions 302, greater than or equal to one hundred twenty eight (128) control circuitry regions 302, greater than or equal to two hundred fifty six (256) control circuitry regions 302, greater than or equal to five hundred twelve (512) control circuitry regions 302, or greater than or equal to one thousand twenty-four (1024) control circuitry regions 302. In some embodiments, a quantity of the control circuitry regions 302 of the control circuitry structure 300 substantially equals a quantity of the array regions 202 (FIG. 2) of the memory array structure 200 (FIG. 2).

Within a horizontal area of an individual control circuitry region 302, the control circuitry structure 300 may include, without limitation, SA sub-regions 310 and SWD sub-regions 312. An individual control circuitry region 302 may include two (2) SA sub-regions 310 (e.g., a first SA sub-region 310A and a second SA sub-region 310B), and two (2) SWD sub-regions 312 (e.g., a first SWD sub-region 312A and a second SWD sub-region 312B). The SA sub-regions 310 and SWD sub-regions 312 of respective control circuitry regions 302 of the control circuitry structure 300 are described in further detail below.

The SA sub-regions 310 of the control circuitry structure 300 may individually include SA devices and circuitry coupled to digit line structures within the memory array structure 200 (FIGS. 1 and 2). The SA sub-regions 310 may be substantially confined within horizontal areas of the control circuitry regions 302, and may individually be horizontally positioned, in the Y-direction, at or proximate a side (e.g., a horizontal boundary) of a respective control circuitry region 302. An individual control circuitry region 302 may include one (1) first SA sub-region 310A and one (1) second SA sub-region 310B. The first SA sub-region 310A may horizontally neighbor, in the Y-direction, one (1) of the digit line contact regions 304 at a first horizontal boundary of the control circuitry region 302; and the second SA sub-region 310B may horizontally neighbor, in the Y-direction, an additional one (1) of the digit line contact regions 304 at a second horizontal boundary of the control circuitry region 302. In some embodiments, for an individual control circuitry region 302, the first SA sub-region 310A thereof is directly horizontally adjacent, in the Y-direction, the first horizontal boundary of the control circuitry region 302 in the Y-direction; and the second SA sub-region 310B thereof is directly horizontally adjacent, in the Y-direction, the second horizontal boundary of the control circuitry region 302 in the Y-direction. In additional embodiments, for one or more of the control circuitry regions 302, the positions of the first SA sub-region 310A and the second SA sub-region 310B thereof are switched (e.g., swapped) relative to the arrangements depicted in FIG. 3.

As shown in FIG. 3, the SA sub-regions 310 (e.g., first SA sub-region 310A and the second SA sub-region 310B) may respectively exhibit a generally rectangular horizontal cross-sectional shape. Major (e.g., relatively larger) sides of an individual SA sub-region 310 may horizontally extend, in the X-direction, from and between two (2) different word line contact regions 306 horizontally neighboring opposing sides (e.g., opposing horizontal boundaries) of the control circuitry region 302 containing the SA sub-region 310. In addition, minor (e.g., relatively smaller) sides of the SA sub-region 310 may horizontally extend, in the Y-direction, from one (1) of the digit line contact regions 304 horizontally neighboring additional opposing sides (e.g., additional opposing horizontal boundaries) of the control circuitry region 302 toward a horizontal center of the control circuitry region 302.

Within an individual control circuitry region 302, the first SA sub-region 310A thereof may include one of odd SA devices operatively associated with (e.g., coupled to) odd digit line structures of the memory array structure 200 (FIGS. 1 and 2) and even SA devices operatively associated with (e.g., coupled to) even digit line structures of the memory array structure 200 (FIGS. 1 and 2); and the second SA sub-region 310B thereof may include the other of odd SA devices and even SA devices. Odd digit line structures of the memory array structure 200 (FIGS. 1 and 2) may be coupled to odd columns of memory cells of the memory array structure 200 (FIGS. 1 and 2), and even digit line structures of the memory array structure 200 (FIGS. 1 and 2) may be coupled to even columns of memory cells of the memory array structure 200 (FIGS. 1 and 2). In some embodiments, the first SA sub-regions 310A include odd SA devices operatively associated with odd digit line structures of the memory array structure 200 (FIGS. 1 and 2), and the second SA sub-regions 310B include even SA devices operatively associated with even digit line structures of the memory array structure 200 (FIGS. 1 and 2). In additional embodiments, the first SA sub-regions 310A include even SA devices operatively associated with even digit line structures of the memory array structure 200 (FIGS. 1 and 2), and the second SA sub-regions 310B include odd SA devices operatively associated with odd digit line structures of the memory array structure 200 (FIGS. 1 and 2).

The SWD sub-regions 312 of the control circuitry structure 300 may individually include SWD devices and circuitry coupled to word line structures within the memory array structure 200 (FIGS. 1 and 2). The SWD sub-regions 312 may be substantially confined within horizontal areas of the control circuitry regions 302. Within an individual control circuitry region 302, the SWD sub-regions 312 thereof may be horizontality interposed, in the Y-direction, between the two (2) SA sub-regions 310 (e.g., the first SA sub-region 310A, the second SA sub-region 310B) of the control circuitry region 302; and may individually be horizontally positioned, in the X-direction, at or proximate an additional side (e.g., an additional horizontal boundary) of the control circuitry region 302. An individual control circuitry region 302 may include one (1) first SWD sub-region 312A and one (1) second SWD sub-region 312B. The first SWD sub-region 312A may horizontally neighbor, in the X-direction, one (1) of the word line contact regions 306 at a first additional horizontal boundary of the control circuitry region 302; and the second SWD sub-region 312B may horizontally neighbor, in the X-direction, an additional one (1) of the word line contact regions 306 at a second additional horizontal boundary of the control circuitry region 302. In some embodiments, for an individual control circuitry region 302, the first SWD sub-region 312A thereof is directly horizontally adjacent, in the X-direction, the first additional horizontal boundary of the control circuitry region 302 in the X-direction; and the first SWD sub-region 312A horizontally extends, in the Y-direction, from and between the first SA sub-region 310A and the second SA sub-region 310B of the control circuitry region 302. Furthermore, in some embodiments, for an individual control circuitry region 302, the second SWD sub-region 312B thereof is directly horizontally adjacent, in the X-direction, the second additional horizontal boundary of the control circuitry region 302 in the X-direction; and the second SWD sub-region 312B horizontally extends, in the Y-direction, from and between the first SA sub-region 310A and the second SA sub-region 310B of the control circuitry region 302. In additional embodiments, for one or more of the control circuitry regions 302, the positions of the first SWD sub-region 312A and the second SWD sub-region 312B thereof are switched (e.g., swapped) relative to the arrangements depicted in FIG. 3.

Each SWD sub-region 312 (e.g., the first SWD sub-region 312A, the second SWD sub-region 312B) within an individual control circuitry region 302 of the control circuitry structure 300 may have multiple sections 314, including a central section 314A and two (2) arm sections 314B. For an individual SWD sub-region 312, a first of the two (2) arm sections 314B thereof may be located at a first end of the central section 314A thereof in the Y-direction; and second of the two (2) arm sections 314B thereof may be located at a second, opposing end of the central section 314A thereof in the Y-direction. The central section 314A thereof may horizontally extend, in the Y-direction, from and between the two (2) arm sections 314B thereof. In addition, for an individual SWD sub-region 312, each of the two (2) arm sections 314B thereof may horizontally extend (e.g., project), in the X-direction, away from the central section 314A of the SWD sub-region 312 toward a horizontal center of the control circuitry region 302 containing the SWD sub-region 312.

As shown in FIG. 3, for an individual SWD sub-region 312, the central section 314A the arm sections 314B thereof may exhibit generally rectangular horizontal cross-sectional shapes, which, in combination, provide the SWD sub-region 312 with an irregular horizontal cross-sectional shape. For individual SWD sub-region 312, the irregular horizontal cross-sectional shape thereof may be characterized as a “folded” horizontal cross-sectional shape, since the two (2) arm sections 314B of the SWD sub-region 312 effectively horizontally fold (e.g., bend, protrude) inward, in the X-direction, relative to the central section 314A of the SWD sub-region 312. A rectangular horizontal cross-sectional geometry (e.g., dimensions and/or shape) of the central section 314A thereof may be different than rectangular horizontal cross-sectional geometries (e.g., dimensions and/or shapes) of the two (2) arm sections 314B thereof. The rectangular horizontal cross-sectional geometries of the two (2) arm sections 314B may be substantially the same as one another or may be different than one another. In some embodiments, for an individual SWD sub-region 312, the rectangular horizontal cross-sectional geometries of the two (2) arm sections 314B thereof are substantially the same as one another and are different than the horizontal cross-sectional geometry of the central section 314A thereof.

Within an individual control circuitry region 302, the first SWD sub-region 312A thereof may include one of odd SWD devices operatively associated with (e.g., coupled to) odd word line structures of the memory array structure 200 (FIGS. 1 and 2) and even SWD devices operatively associated with (e.g., coupled to) even word line structures of the memory array structure 200 (FIGS. 1 and 2); and the second SWD sub-region 312B thereof may include the other of odd SWD devices and even SWD devices. Odd word line structures of the memory array structure 200 (FIGS. 1 and 2) may be coupled to odd rows of memory cells of the memory array structure 200 (FIGS. 1 and 2), and even word line structures of the memory array structure 200 (FIGS. 1 and 2) may be coupled to even rows of memory cells of the memory array structure 200 (FIGS. 1 and 2). In some embodiments, the first SWD sub-regions 312A include odd SWD devices operatively associated with odd word line structures of the memory array structure 200 (FIGS. 1 and 2), and the second SWD sub-regions 312B include even SWD devices operatively associated with even word line structures of the memory array structure 200 (FIGS. 1 and 2). In additional embodiments, the first SWD sub-regions 312A include even SWD devices operatively associated with even word line structures of the memory array structure 200 (FIGS. 1 and 2), and the second SWD sub-regions 312B include odd SWD devices operatively associated with odd word line structures of the memory array structure 200 (FIGS. 1 and 2).

Still referring to FIG. 3, the digit line contact regions 304 of the control circuitry structure 300 may comprise horizontal areas of the control circuitry structure 300 including additional routing structures and additional contact structures coupled to respective digit line structures of the memory array structure 200 (FIGS. 1 and 2) terminating within respective digit line exit regions 204 (FIG. 2) of the memory array structure 200 (FIGS. 1 and 2). As described in further detail below, the additional routing structures and the additional contact structures within the digit line contact regions 304 of the control circuitry structure 300 may be coupled to routing structures and contact structures within the digit line exit regions 204 (FIG. 2) of the memory array structure 200 (FIGS. 1 and 2). At least some of the additional routing structures and the additional contact structures within the digit line contact regions 304 may couple the digit line structures of the memory array structure 200 (FIGS. 1 and 2) to SA devices within the SA sub-regions 310 of the control circuitry structure 300. The digit line contact regions 304 of the control circuitry structure 300 are configured to at least partially (e.g., substantially) horizontally overlap respective digit line exit regions 204 (FIG. 2) of the memory array structure 200 (FIGS. 1 and 2). In some embodiments, a quantity of the digit line contact regions 304 of the control circuitry structure 300 substantially equals a quantity of the digit line exit regions 204 (FIG. 2) of the memory array structure 200 (FIGS. 1 and 2). As shown in FIG. 3, in some embodiments, the digit line contact regions 304 horizontally extend in the X-direction, and are respectively horizontally interposed, in the Y-direction, between neighboring control circuitry regions 302. The digit line contact regions 304 may, for example, horizontally alternate with the control circuitry regions 302 in the Y-direction.

The word line contact regions 306 of the control circuitry structure 300 may comprise additional horizontal areas of the control circuitry structure 300 including additional routing structures and additional contact structures coupled to respective word line structures of the memory array structure 200 (FIGS. 1 and 2) terminating within respective word line exit regions 206 (FIG. 2) of the memory array structure 200 (FIGS. 1 and 2). As described in further detail below, the additional routing structures and the additional contact structures within the word line contact regions 306 of the control circuitry structure 300 may be coupled to routing structures and contact structures within the word line exit regions 206 (FIG. 2) of the memory array structure 200 (FIGS. 1 and 2). At least some of the additional routing structures and the additional contact structures within the word line contact regions 306 may couple the word line structures of the memory array structure 200 (FIGS. 1 and 2) to SWD devices within the SWD sub-regions 312 of the control circuitry structure 300. The word line contact regions 306 of the control circuitry structure 300 are configured to at least partially (e.g., substantially) horizontally overlap respective word line exit regions 206 (FIG. 2) of the memory array structure 200 (FIGS. 1 and 2). In some embodiments, a quantity of the word line contact regions 306 of the control circuitry structure 300 substantially equals a quantity of the word line exit regions 206 (FIG. 2) of the memory array structure 200 (FIGS. 1 and 2). As shown in FIG. 3, in some embodiments, the word line contact regions 306 horizontally extend in the Y-direction, and are respectively horizontally interposed, in the X-direction, between neighboring control circuitry regions 302. The word line contact regions 306 may, for example, horizontally alternate with the control circuitry regions 302 in the X-direction.

The additional minigap regions 308 of the control circuitry structure 300 may comprise additional horizontal areas of the control circuitry structure 300 at least including further routing structures (e.g., control signal routing structures, column select routing structures, global input/output (GIO) routing structures, local input/output (LIO) routing structures, bussing routing structures) of the microelectronic device 100 (FIG. 1) within a horizontal area thereof. For an additional minigap regions 308, the further routing structures may individually horizontally extend (e.g., in the X-direction, in the Y-direction) through the additional minigap regions 308 en route to various circuitry and devices of the control circuitry structure 300. Different further routing structures within horizontal areas of the additional minigap regions 308 may be positioned at different vertical elevations (e.g., in the Z-direction) than one another. The additional minigap regions 308 of the control circuitry structure 300 are configured to at least partially (e.g., substantially) horizontally overlap respective minigap regions 208 (FIG. 2) of the memory array structure 200 (FIGS. 1 and 2). In some embodiments, a quantity of the additional minigap regions 308 of the control circuitry structure 300 substantially equals a quantity of the minigap regions 208 (FIG. 2) of the memory array structure 200 (FIGS. 1 and 2). As shown in FIG. 3, some of the additional minigap regions 308 may individually be horizontally positioned between opposing corners of at least two (2) (e.g., two, four) of the control circuitry regions 302 horizontally neighboring one another. An individual additional minigap region 308 may be horizontally interposed, in the X-direction, between two (2) neighboring digit line contact regions 304; and may be substantially horizontally aligned, in the Y-direction, with each of the two (2) neighboring digit line contact regions 304. In addition, an individual additional minigap region 308 may be horizontally interposed, in the Y-direction, between two (2) neighboring word line contact regions 306; and may be substantially horizontally aligned, in the X-direction, with each of the two (2) neighboring word line contact regions 306.

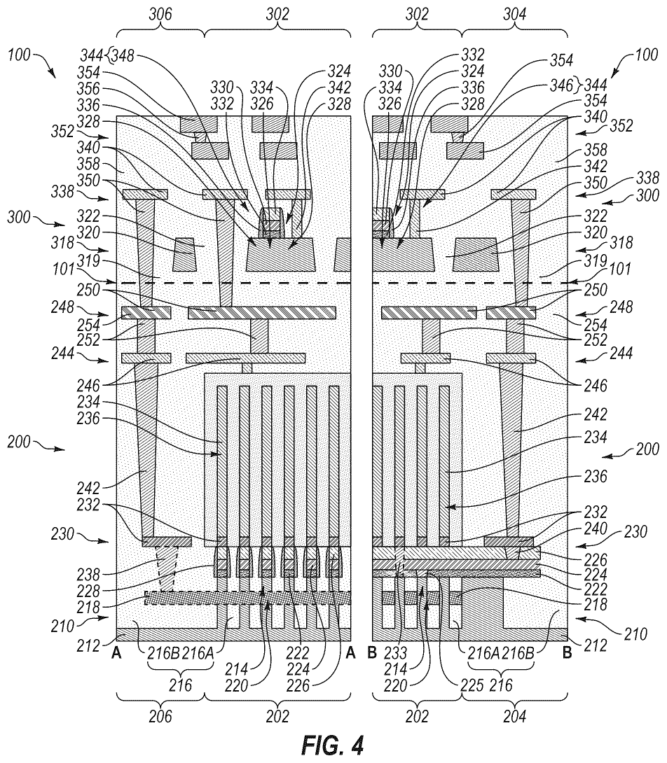

FIG. 4 is a diagram showing different vertical cross sectional views of the microelectronic device 100 collectively shown in FIGS. 1 through 3, taken about lines A-A and B-B depicted in FIGS. 2 and 3. The vertical cross section of the microelectronic device 100 about line A-A is a view of an XZ-plane of a portion of the microelectronic device 100 horizontally overlapping one of the array regions 202 and one of the word line exit regions 206 of the memory array structure 200, and one of the control circuitry regions 302 and one of the word line contact regions 306 of the control circuitry structure 300. The vertical cross section of the microelectronic device 100 about line B-B is a view of an YZ-plane of a portion of the microelectronic device 100 horizontally overlapping the one of the array regions 202 and one of the digit line exit regions 204 of the memory array structure 200, and the one of the control circuitry regions 302 and one of the digit line contact regions 304 of the control circuitry structure 300. Within the microelectronic device 100, the control circuitry regions 302 of the control circuitry structure 300 vertically overlie and horizontally overlap the array regions 202 of the memory array structure 200; the digit line contact regions 304 of the control circuitry structure 300 vertically overlie and horizontally overlap the digit line exit regions 204 of the memory array structure 200; and the word line contact regions 306 of the control circuitry structure 300 vertically overlie and horizontally overlap the word line exit regions 206 of the memory array structure 200.

As shown in FIG. 4, the memory array structure 200 of the microelectronic device 100 may include a base structure 210 including semiconductor material 212 and isolation structures 216 (e.g., shallow trench isolation (STI) structures) vertically extending into the semiconductor material 212. The isolation structures 216 may define boundaries of active regions 214 of the semiconductor material 212, as described in further detail below.

The base structure 210 comprises a base material or construction upon which additional features (e.g., materials, structures, devices) of the memory array structure 200 are formed. The base structure 210 may comprise a semiconductor structure (e.g., a semiconductor wafer), or a base semiconductor material on a supporting structure. For example, the base structure 210 may comprise a conventional silicon substrate (e.g., a conventional silicon wafer), or another bulk substrate comprising a semiconductor material. In some embodiments, the base structure 210 comprises a silicon wafer. The base structure 210 may include one or more layers, structures, and/or regions formed therein and/or thereon.

The isolation structures 216 of the memory array structure 200 may include trenches (e.g., openings, vias, apertures) within the semiconductor material 212 of base structure 210 filled with insulative material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric nitride material (e.g., SiN_{y}), at least one dielectric oxynitride material (e.g., SiOₓN_{y}), at least one dielectric carboxynitride material (e.g., SiOₓC_{z}N_{y}), and amorphous carbon. In some embodiments, the isolation structures 216 are respectively formed of and include SiOₓ (e.g., SiO₂).

The isolation structures 216 may include first isolation structures 216A and second isolation structures 216B. The first isolation structures 216A may have one or more different geometric configuration(s) (e.g., different dimension(s), different shape(s)) and different horizontal positioning relative to the second isolation structures 216B. As shown in FIG. 4, in some embodiments, the first isolation structures 216A are respectively positioned within a horizontal area of a respective array region 202 of the memory array structure 200; and the second isolation structures 216B are respectively positioned within a horizontal area of a respective digit line exit regions 204 or a respective word line exit region 206 of the memory array structure 200. In addition, at least some of the first isolation structures 216A may respectively have different horizontal dimension(s) than at least some of the second isolation structures 216B. At least some of the isolation structures 216 (e.g., at least some of the first isolation structures 216A and/or at least some of the second isolation structures 216B) vertically extend to and terminate at a different vertical position than some other of the isolation structures 216 (e.g., at least some other of the first isolation structures 216A and/or at least some other of the second isolation structures 216B). For example, some of the isolation structures 216 may be formed to be relatively vertically shallower than some other of the isolation structures 216. Some of the isolation structures 216 may be employed as shallow trench isolation (STI) structures within the base structure 210.

Within an individual array region 202 of the memory array structure 200, some of the isolation structures 216 (e.g., some of the first isolation structures 216A) may at least partially define boundaries of the active regions 214 of the semiconductor material 212 of the base structure 210. The active regions 214 of the semiconductor material 212 may individually vertically extend (e.g., project) from a relatively lower portion of the semiconductor material 212 that horizontally extends across and between the active regions 214. The active regions 214 may be considered pillar structures of the semiconductor material 212.

The active regions 214 of the semiconductor material 212 may individually exhibit an elongate (e.g., non-circular, non-square) horizontal cross-sectional shape at least partially defined by the horizontal cross-sectional shapes of the first isolation structures 216A horizontally adjacent thereto. The active regions 214 may individually include an upper surface, opposing horizontal ends, and opposing horizontal sides extending from and between the opposing ends. Intersections of the opposing horizontal ends of an individual active region 214 with the opposing horizontal sides of the active region 214 may define horizontal corners of the active region 214. As shown in FIG. 4, the upper surfaces of the active regions 214 may be substantially coplanar with one another. In addition, an individual active region 214 may include a digit line contact region (e.g., bit line contact region) and storage node contact regions (e.g., cell contact regions). The storage node contact regions of the active region 214 may be located proximate the opposing horizontal ends of the active region 214, and the digit line contact region may be horizontally interposed between the storage node contact regions. The digit line contact region may be positioned at or proximate to a horizontal center of the active region 214. In some embodiments, the digit line contact region of an individual active region 214 is horizontally narrower (e.g., in the X-direction shown in FIGS. 1 through 3) than each of the storage node contact regions of the active region 214. The digit line contact region and the storage node contact regions of an individual active region 214 may be separated from one another by a pair of the first isolation structures 216A.

With continued reference to FIG. 4, word line structures 218 may be at least partially embedded within the isolation structures 216 and may horizontally extend in parallel in the X-direction (FIG. 1A) completely through the array region 202 and at least partially through the word line exit region 206. At least some of the word line structures 218 may terminate within the word line exit region 206. In FIG. 4, the illustrated word line structure 218 is depicted by way of dashed lines to represent that it is outside of (e.g., horizontally offset in the Y-direction (FIGS. 1 through 3) from) the vertical plane (e.g., XZ-plane) of line A-A. Tops (e.g., upper vertical boundaries) of the word line structures 218 may be substantially coplanar with one another. Side surfaces and a bottom surface of an individual word line structure 218 may be covered by insulative material of a respective one of the isolation structures 216. For example, portions of the isolation structure 216 may be horizontally interposed between the word line structure 218 and a respective active region 214 of the semiconductor material 212 of the base structure 210. The word line structures 218 may individually be formed of and include conductive material. In some embodiments, the word line structures 218 are individually formed of and include one or more of W, Ru, Mo, and TiN_{y}.

Within the array region 202, the memory array structure 200 further includes access devices 220. The access devices 220 may individually include a channel region comprising a portion of an active region 214 of the semiconductor material 212 of the base structure 210; a source region and a drain region respectively horizontally neighboring the channel region and individually comprising a conductively doped portion of the active region 214 of the semiconductor material 212 of the base structure 210; at least one gate comprising a portion of at least one of the word line structures 218; and a gate dielectric structure comprising a portion of the insulative material of the first isolation structure 216A interposed between the channel region thereof and the gate thereof.

The memory array structure 200 may further include a first dielectric material 222 on or over the base structure 210. Within the array region 202, the first dielectric material 222 may overlie the access devices 220. The first dielectric material 222 may be formed of and include insulative material. In some embodiments, the first dielectric material 222 is formed of and includes dielectric oxide material (e.g., SiOₓ, such as SiO₂).

With continued reference to FIG. 4, digit line structures 224 may vertically overlie the first dielectric material 222 and may individually horizontally extend in parallel in the Y-direction (FIGS. 1 through 3) completely through a respective array region 202 and at least partially through a respective digit line exit region 204. At least some of the digit line structures 224 may terminate within the digit line exit region 204. As shown in FIG. 4, tops (e.g., upper vertically boundaries) of the digit line structures 224 may be substantially coplanar with one another. The digit line structures 224 may individually be formed of and include conductive material. In some embodiments, the digit line structures 224 are individually formed of and include one or more of W, Ru, Mo, and TiN_{y}.

Still referring to FIG. 4, digit line capping structures 226 may be formed on or over upper surfaces of the digit line structures 224, and digit line spacer structures 228 may be formed on or over side surfaces (e.g., sidewalls) of the digit line structures 224. The digit line capping structures 226 may at least partially (e.g., substantially) cover the upper surfaces of the digit line structures 224, and the digit line spacer structures 228 may at least partially (e.g., substantially) cover the side surfaces of the digit line structures 224. As shown in FIG. 4, in some embodiments, upper boundaries of the digit line spacer structures 228 vertically overlie the upper surfaces of the digit line structures 224, and lower boundaries of the digit line spacer structures 228 vertically underlie lower surfaces of the digit line structures 224. The digit line capping structures 226 and the digit line spacer structures 228 may individually be formed of and include at least one insulative material. In some embodiments, the digit line capping structures 226 and the digit line spacer structures 228 are individually formed of and include one or more of dielectric oxide material (e.g., SiOₓ, such as SiO₂) and dielectric nitride material (e.g., SiN_{y}, such as Si₃N₄).

Within the array region 202, the memory array structure 200 may further include first digit line contact structures 225 (also referred to herein as “DIGITCON” structures) vertically overlying and in contact with the active regions 214 of the semiconductor material 212 of the base structure 210. The first digit line contact structures 225 may vertically extend through the first dielectric material 222 and into the active regions 214 of the semiconductor material 212 of the base structure 210. The first digit line contact structures 225 horizontally overlap (e.g., in the X-direction and the Y-direction shown in FIGS. 1 through 3) digit line contact sections of the active regions 214. The first digit line contact structures 225 may respectively vertically extend from a digit line contact section of an individual active region 214, through the first dielectric material 222, and to an individual digit line structure 224. An individual first digit line contact structure 225 may be horizontally interposed between two (2) of the word line structures 218 (and, hence, two (2) of the isolation structures 216) neighboring one another in the Y-direction (FIGS. 1 through 3), and may be horizontally interposed between two (2) of storage node contact sections of an individual active region 214 in an additional horizontal direction angled relative to the Y-direction (FIGS. 1 through 3) and the X-direction (FIGS. 1 through 3). An individual first digit line contact structure 225 may be coupled to one of the source/drain regions (e.g., the source region) of an individual access device 220 of the memory array structure 200. Within the horizontal area of an individual active region 214, an individual first digit line contact structure 225 may be coupled to two (2) (e.g., a pair) of the access devices 220 operatively associated with the active region 214. For example, the two (2) of the access devices 220 may share a source region within the active region 214 with one another, and the first digit line contact structure 225 may be coupled to the shared source region of the two (2) of the access devices 220. The first digit line contact structures 225 may individually be formed of and include conductive material.

Within the array region 202, the memory array structure 200 may further include storage node contact structures 233 (also referred to herein as “CELLCON” structures) vertically overlying and in contact with the active regions 214 of the semiconductor material 212 of the base structure 210. The storage node contact structures 233 may vertically extend through the first dielectric material 222 and into the active regions 214 of the semiconductor material 212 of the base structure 210. The storage node contact structures 233 horizontally overlap (e.g., in the X-direction and the Y-direction shown in FIGS. 1 through 3) storage node contact sections of the active regions 214. In FIG. 4, the illustrated storage node contact structure 233 is depicted by way of dashed lines to represent that it is outside of (e.g., horizontally offset in the X-direction (FIGS. 1 through 3) from) the vertical plane (e.g., YZ-plane) of line B-B. The storage node contact structures 233 may respectively vertically extend from a storage node contact section of an individual active region 214, through the first dielectric material 222, and to first routing structure 232 vertically overlying the digit line capping structures 226. An individual storage node contact structure 233 may be horizontally interposed between two (2) of the word line structures 218 (and, hence, two (2) of the isolation structures 216) neighboring one another in the Y-direction (FIGS. 1 through 3), and may horizontally neighbor the digit line contact section of an individual active region 214 in an additional horizontal direction angled relative to the Y-direction (FIGS. 1 through 3) and the X-direction (FIGS. 1 through 3). An individual storage node contact structure 233 may be coupled to one of the source/drain regions (e.g., the drain region) of an individual access device 220 of the memory array structure 200. Within the horizontal area of an individual active region 214, an individual storage node contact structure 233 may be coupled to one (1) of two (2) (e.g., a pair) of access devices 220 operatively associated with the active region 214. For example, the two (2) of the access devices 220 have separate drain regions than one another within the active region 214, and the individual storage node contact structure 233 may be coupled to the drain region of one (1) of the two (2) of the access devices 220. An individual active region 214 of the semiconductor material 212 may have two (2) storage node contact structures 233 in contact therewith. The storage node contact structures 233 may individually be formed of and include conductive material.

Still referring to FIG. 4, a first routing tier 230 may be formed to vertically overlie the digit line capping structures 226 and may include first routing structures 232. Within the array region 202, at least some of the first routing structures 232 may, for example, be employed to facilitate a horizontal arrangement (e.g., a hexagonal close packed arrangement) of storage node devices 234 that is different than a horizontal arrangement of the storage node contact structures 233, while electrically connecting the storage node contact structures 233 (and, hence, the access devices 220) to the storage node devices 234. In addition, within the digit line exit regions 204 and the word line exit regions 206, at least some other of the first routing structures 232 may vertically extend between and couple vertically neighboring conductive contact structures within the digit line exit regions 204 and the word line exit regions 206, as described in further detail below. The first routing structures 232 may individually be formed of and include conductive material. In some embodiments, the first routing structures 232 are individually formed of and include one or more of W, Ru, Mo, and TiN_{y}.

Within the array region 202, the storage node devices 234 (e.g., capacitors) may be formed on or over the first routing structures 232. The storage node devices 234 may be in electrical contact with the first routing structures 232, and, hence with the storage node contact structures 233 and the access devices 220. The storage node devices 234 may be coupled to the access devices 220 by way of the storage node contact structures 233 and the first routing structures 232 to form memory cells 236 (e.g., DRAM cells) within the array region 202. Each memory cell 236 may individually include one of the access devices 220, one of the storage node devices 234, one of the storage node contact structures 233, and one of the first routing structures 232. The storage node devices 234 may individually be formed and configured to store a charge representative of a programmable logic state of the memory cell 236 including the storage node device 234. In some embodiments, the storage node devices 234 are capacitors. During use and operation, a charged capacitor may represent a first logic state, such as a logic 1; and an uncharged capacitor may represent a second logic state, such as a logic 0. Each of the storage node devices 234 may, for example, be formed to include a first electrode (e.g., a bottom electrode), a second electrode (e.g., a top electrode), and a dielectric material between the first electrode and the second electrode.

Still referring to FIG. 4, the memory array structure 200 may further include a second routing tier 244 vertically overlying the memory cells 236 and including second routing structures 246. The second routing structures 246 may, for example, include one or more of pad structures and line structures. The second routing structures 246 may respectively be formed of and include conductive material. In some embodiments, the second routing structures 246 are individually formed of and include one or more of W, Ru, Mo, and TiN_{y}.

Within the word line exit regions 206, the memory array structure 200 further includes word line contact structures 238. Within an individual word line exit region 206, the word line contact structures 238 may vertically extend between and couple some of the first routing structures 232 and some of the word line structures 218. The word line contact structures 238 may be considered to be so-called “edge of array” word line contact structures. In the FIG. 4, the illustrated word line contact structures 238 is depicted by way of dashed lines to represent that it is outside of (e.g., horizontally offset in the Y-direction (FIGS. 1 through 3) from) the vertical plane (e.g., XZ-plane) of line A-A. An individual word line contact structure 238 may be formed to have an upper surface in physical contact with one of the first routing structures 232; and a lower surface on, within, or below one of the word line structures 218. The word line contact structures 238 may respectively be formed of and include conductive material. In some embodiments, the word line contact structures 238 are individually formed of and include one or more of W, Ru, Mo, and TiN_{y}.

Within the digit line exit regions 204, the memory array structure 200 further includes second digit line contact structures 240. Within an individual digit line exit region 204, the second digit line contact structures 240 may vertically extend between and couple some of the first routing structures 232 and some of the digit line structures 224. The second digit line contact structures 240 may be considered to be so-called “edge of array” digit line contact structures. An individual second digit line contact structure 240 may be formed to have an upper surface in physical contact with one of the first routing structures 232; and a lower surface on, within, or below one of the digit line structures 224. The second digit line contact structures 240 may respectively be formed of and include conductive material. In some embodiments, the second digit line contact structures 240 are individually formed of and include one or more of W, Ru, Mo, and TiN_{y}.

Within the word line exit regions 206 and the digit line exit regions 204, the memory array structure 200 further includes first contact structures 242 (e.g., deep contact structures). The first contact structures 242 vertically extend between and couple some of the first routing structures 232 of the first routing tier 230 and some of the second routing structures 246 of the second routing tier 244. An individual first contact structure 242 may have an upper surface in physical contact with one of the second routing structures 246; and a lower surface on, within, or below one of the first routing structures 232. The first contact structures 242 may be considered to be so-called “edge of array” contact structures. The first contact structures 242 may respectively be formed of and include conductive material. In some embodiments, the first contact structures 242 are individually formed of and include one or more of W, Ru, Mo, and TiN_{y}.

Still referring to FIG. 4, the memory array structure 200 may further include a third routing tier 248 vertically overlying the second routing tier 244 and including third routing structures 250. The third routing structures 250 may, for example, include one or more of pad structures and line structures. In addition, the memory array structure 200 may also include second contact structures 252. The second contact structures 252 vertically extend between and couple some of the second routing structures 246 of the second routing tier 244 and some of the third routing structures 250 of the third routing tier 248. An individual second contact structure 252 may have an upper surface in physical contact with one of the third routing structures 250; and a lower surface on, within, or below one of the second routing structures 246. The third routing structures 250 and the second contact structures 252 may respectively be formed of and include conductive material. In some embodiments, the third routing structures 250 and the second contact structures 252 are individually formed of and include one or more of W, Ru, Mo, and TiN_{y}.

Isolation material 254 may be formed on or over portions of at least the base structure 210, the first dielectric material 222, the digit line capping structures 226, the first routing structures 232, the storage node devices 234, the memory cells 236, the first contact structures 242, the second routing structures 246, the second contact structures 252, and the third routing structures 250. The isolation material 254 may be formed of and include insulative material. In some embodiments, the isolation material 254 is formed of and includes dielectric oxide material, such as SiOₓ (e.g., SiO₂). The isolation material 254 may be substantially homogeneous, or the isolation material 254 may be heterogeneous. In some embodiments, a portion of the isolation material 254 vertically overlies upper surfaces of the uppermost ones of the third routing structures 250.

Still referring next to FIG. 4, the control circuitry structure 300 of the microelectronic device 100 may be formed to include an additional base structure 318 including additional isolation material 319, additional semiconductor material 320 on or over the additional isolation material 319, and additional isolation structures 322 vertically extending through the additional semiconductor material 320 to the additional isolation material 319. The additional isolation material 319 may be bonded (e.g., dielectric-to-dielectric bonded, such as oxide-to-oxide bonded) to the isolation material 254 of the memory array structure 200 of the microelectronic device 100.

The additional base structure 318 comprises a base material or construction upon which additional features (e.g., materials, structures, devices) of the control circuitry structure 300 are formed. The additional base structure 318 may comprise a semiconductor structure (e.g., a semiconductor wafer), or a base semiconductor material on a supporting structure. For example, the additional base structure 318 may comprise a conventional silicon substrate (e.g., a conventional silicon wafer), or another bulk substrate comprising a semiconductor material. In some embodiments, the additional base structure 318 comprises a silicon wafer. The additional base structure 318 may include one or more layers, structures, and/or regions formed therein and/or thereon.

The additional isolation material 319 is formed of and includes insulative material. For example, the additional isolation material 319 may be formed of and includes dielectric oxide material, such as SiOₓ (e.g., SiO₂). The additional isolation material 319 may be substantially homogeneous, or the additional isolation material 319 may be heterogeneous.

The additional isolation structures 322 may comprise trenches (e.g., openings, vias, apertures) within the additional semiconductor material 320 of the additional base structure 318 filled with insulative material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric nitride material (e.g., SiN_{y}), at least one dielectric oxynitride material (e.g., SiOₓN_{y}), at least one dielectric carboxynitride material (e.g., SiOₓC_{z}N_{y}), and amorphous carbon. In some embodiments, the additional isolation structures 322 are respectively formed of and include SiOₓ (e.g., SiO₂).

Still referring to FIG. 4, the control circuitry structure 300 may further include transistors 324. The transistors 324 may individually include conductively doped regions 328 (e.g., source/drain regions), a channel region 326, a gate structure 330 (e.g., a gate electrode), and a gate dielectric material 332. For an individual transistor 324, the conductively doped regions 328 thereof may be formed within the additional semiconductor material 320 of the additional base structure 318; the channel region 326 thereof may be formed within the additional semiconductor material 320 of the additional base structure 318 and may be horizontally interposed between the conductively doped regions 328 thereof; the gate structure 330 thereof may vertically overlie and horizontally overlap the channel region 326 thereof; and the gate dielectric material 332 (e.g., dielectric oxide material) may be vertically interposed (e.g., in the Z-direction (FIGS. 1 through 3)) between the gate structure 330 and the channel region 326.

For an individual transistor 324, the conductively doped regions 328 thereof may comprise additional semiconductor material 320 of the additional base structure 318 doped with one or more desired conductivity-enhancing dopants. In some embodiments, the conductively doped regions 328 of the transistor 324 comprise the additional semiconductor material 320 doped with at least one N-type dopant (e.g., one or more of phosphorus, arsenic, antimony, and bismuth). In some of such embodiments, the channel region 326 of the transistor 324 comprises the additional semiconductor material 320 doped with at least one P-type dopant (e.g., one or more of boron, aluminum, and gallium). In some other of such embodiments, the channel region 326 of the transistor 324 comprises substantially undoped additional semiconductor material 320. In additional embodiments, for an individual transistor 324, the conductively doped regions 328 thereof comprise the additional semiconductor material 320 doped with at least one P-type dopant (e.g., one or more of boron, aluminum, and gallium). In some of such additional embodiments, the channel region 326 of the transistor 324 comprises the additional semiconductor material 320 doped with at least one N-type dopant (e.g., one or more of phosphorus, arsenic, antimony, and bismuth). In some other of such additional embodiments, the channel region 326 of the transistor 324 comprises substantially undoped additional semiconductor material 320.

The gate structures 330 (e.g., gate electrodes, gates) may individually horizontally extend between and be employed by multiple transistors 324. The gate structures 330 may be formed of and include conductive material. The gate structures 330 may individually be substantially homogeneous, or the gate structures 330 may individually be heterogeneous. In some embodiments, the gate structures 330 are each substantially homogeneous. In additional embodiments, the gate structures 330 are each heterogeneous. Individual gate structures 330 may, for example, be formed of and include a stack of at least two different conductive materials.

Still referring to FIG. 4, gate capping structures 334 may be formed on or over upper surfaces of the gate structures 330; and gate spacer structures 336 may be formed on or over side surfaces (e.g., sidewalls) of the gate structures 330, the gate dielectric material 332, and the gate capping structures 334. The gate capping structures 334 and the gate spacer structures 336 may individually be formed of and include at least one insulative material. In some embodiments, the gate capping structures 334 and the gate spacer structures 336 are individually formed of and include one or more of dielectric oxide material (e.g., SiOₓ, such as SiO₂) and dielectric nitride material (e.g., SiN_{y}, such as Si₃N₄).

Still referring to FIG. 4, the control circuitry structure 300 further includes third contact structures 342 vertically overlying and in contact (e.g., physical contact, electrical contact) with the conductively doped regions 328 of the transistors 324. In some embodiments, the third contact structures 342 vertically overlie, horizontally overlap, and physically contact the conductively doped regions 328 of the transistors 324. The third contact structures 342 may individually be formed of and include conductive material. In some embodiments, the third contact structures 342 are individually formed of and include one or more of W, Ru, Mo, and TiN_{y}.

The control circuitry structure 300 further includes a fourth routing tier 338 vertically over the transistors 324 and including fourth routing structures 340. The fourth routing structures 340 may, for example, include one or more of pad structures and line structures. As shown in FIG. 4, some of the fourth routing structures 340 may be coupled to the third contact structures 342 (and, hence, the transistors 324). The fourth routing structures 340 may respectively be formed of and include conductive material. In some embodiments, the fourth routing structures 340 are individually formed of and include one or more of W, Ru, Mo, and TiN_{y}.

With continued reference to FIG. 4, the transistors 324, the third contact structures 342, and at least some of the fourth routing structures 340 may form control logic circuitry of various control logic devices 344 configured to control various operations of various features (e.g., the memory cells 236) of the microelectronic device 100. In some embodiments, the control logic devices 344 comprise complementary metal-oxide-semiconductor (CMOS) circuitry. As a non-limiting example, the control logic devices 344 may include one or more (e.g., each) of charge pumps (e.g., V_{CCP} charge pumps, V_{NEGWL} charge pumps, DVC2 charge pumps), delay-locked loop (DLL) circuitry (e.g., ring oscillators), V_{dd} regulators, drivers (e.g., main word line drivers, sub word line drivers (SWD)), page buffers, decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, array multiplexers (MUX), error checking and correction (ECC) devices, self-refresh/wear leveling devices, and other chip/deck control circuitry.

Different regions of the control circuitry structure 300 may include different control logic devices 344 formed within horizontal areas thereof. For example, referring collectively to FIGS. 3 and 4, within a horizontal area of an individual SA sub-region 310 (e.g., a first SA sub-region 310A, a second SA sub-region 310B) (FIG. 3) within a respective control circuitry region 302 (e.g., the first control circuitry region 302A (FIG. 3)) of the control circuitry structure 300, the control logic devices 344 may include SA devices 346. As another example, still referring collectively to FIGS. 3 and 4, within a horizontal area of an individual SWD sub-region 312 (e.g., a first SWD sub-region 312A, a second SWD sub-region 312B) (FIG. 3) within a respective control circuitry region 302 (e.g., the first control circuitry region 302A (FIG. 3)), the control logic devices 344 may include SWD devices 348.

Referring to FIG. 4, a front side of the control circuitry structure 300 may be considered to be a side (e.g., end surface) most proximate to the control logic devices 344 (e.g., most proximate to the fourth routing structures 340 of the fourth routing tier 338), and a back side of the control circuitry structure 300 may be considered to be an additional side (e.g., additional end surface) relatively more distal from the control logic devices 344 (e.g., most proximate to the additional isolation material 319) than the front side. In addition, a front side of the memory array structure 200 may be considered to be a side (e.g., end surface) most proximate to the third routing structures 250 of the third routing tier 248, and a back side of the additional memory array structure 200 may be considered to be an additional side (e.g., additional end surface) most proximate to the base structure 210. Accordingly, in the configuration shown in FIG. 4, the microelectronic device 100 may be formed to have a so-called “back-to-front” (B2F) arrangement of the control circuitry structure 300 relative to the memory array structure 200.

Still referring to FIG. 4, fourth contact structures 350 may be formed to vertically extend from some of the fourth routing structures 340 of the fourth routing tier 338 vertically overlying the control logic devices 344 to some of the third routing structures 250 of the third routing tier 248 vertically underlying the control logic devices 344. An individual fourth contact structure 350 may couple at least one of the fourth routing structures 340 to at least one of the third routing structures 250. One or more (e.g., each) of the fourth contact structures 350 may be formed to horizontally overlap and vertically extend through one or more of the additional isolation structures 322 of the control circuitry structure 300. Optionally, one or more other of the fourth contact structures 350 may be formed to horizontally overlap and vertically extend through the additional semiconductor material 320 of the control circuitry structure 300. The fourth contact structures 350 may be formed after bonding the control circuitry structure 300 to the memory array structure 200. The fourth contact structures 350 may respectively be formed of and include conductive material. In some embodiments, the fourth contact structures 350 are individually formed of and include one or more of W, Ru, Mo, and TiN_{y}.

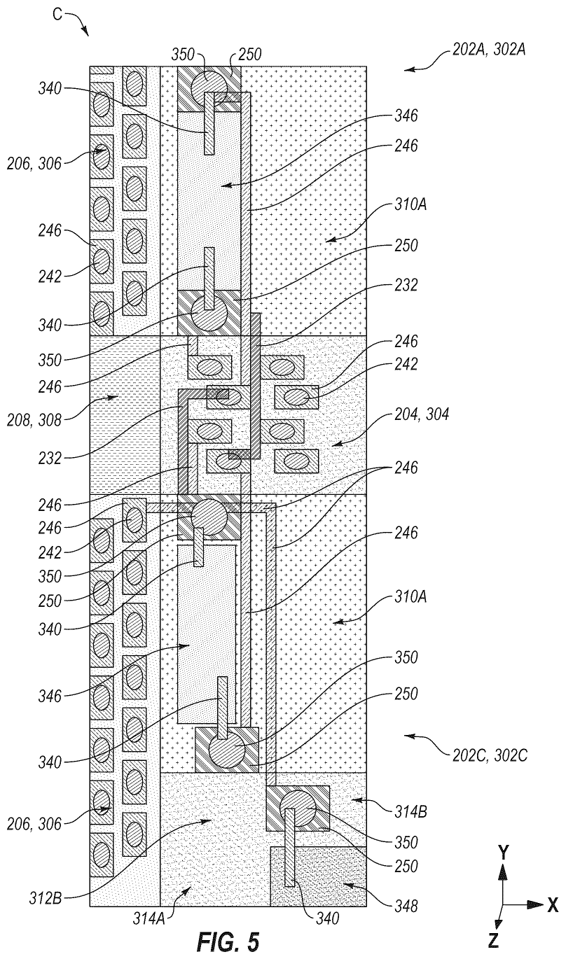

The fourth contact structures 350 may facilitate operable communication between the control logic devices 344 of the control circuitry structure 300 and the memory cells 236 of the memory array structure 200 vertically thereunder. For example, the fourth contact structures 350, in combination at least with the fourth routing structures 340 of the fourth routing tier 338, the third routing structures 250 of the third routing tier 248, the second contact structures 252, the second routing structures 246 of the second routing tier 244, the first contact structures 242, the first routing structures 232 of the first routing tier 230, the second digit line contact structures 240, the digit line structures 224, the first digit line contact structures 225, the word line contact structure 238, and the word line structures 218, may facilitate conductive paths between the different control logic devices 344 of the control circuitry structure 300 and the memory cells 236 of the memory array structure 200. As described in further detail below with reference to FIGS. 5 through 7, in view of configurations of the SWD sub-regions 312 (FIG. 3) and the SA sub-region 310 (FIG. 3) within the control circuitry regions 302 of the control circuitry structure 300, some of the second routing structures 246 of the second routing tier 244, some of the second contact structures 252, and some of the third routing structures 250 of the third routing tier 248 may be employed to position a group of the fourth contact structures 350 coupled to a group of the SWD devices 348 within a horizontal area of a respective arm section 314B (FIG. 3) of an individual SWD sub-region 312 (FIG. 3) while a group of the first contact structures 242 coupled to the group of the SWD devices 348 are positioned within a horizontal area of a respective word line exit region 206 (and, hence, a respective word line contact region 306) of the microelectronic device 100.

Still referring to FIG. 4, the microelectronic device 100 further includes BEOL structures formed vertically over the fourth routing tier 338. For example, at least one additional routing tier 352 (e.g., at least two additional routing tiers, at least three additional routing tiers, at least four additional routing tiers, at least five additional routing tiers) respectively including additional routing structures 354. In addition, additional contact structures 356 may couple different additional routing structures 354 to one another, as desired. The additional routing structures 354 and the additional contact structures 356 may respectively be formed of and include conductive material. In some embodiments, the additional routing structures 354 and additional contact structures 356 are individually formed of and include one or more of W, Cu, Al, Ru, Mo, and TiN_{y}.

A further isolation material 358 may be formed on or over portions of at least the control logic devices 344 (including the transistors 324, the third contact structure 342, and the fourth routing structures 340 thereof), the fourth contact structures 350, and the BEOL structures (including the additional routing structures 354 and the additional contact structures 356 thereof). The further isolation material 358 may be formed of and include insulative material. In some embodiments, the further isolation material 358 is formed of and includes a dielectric oxide material, such as SiOₓ (e.g., SiO₂). The further isolation material 358 may be substantially homogeneous, or the further isolation material 358 may be heterogeneous.

FIGS. 5 through 7 are simplified, partial top-down views of the microelectronic device 100 collectively shown in FIGS. 1 through 4, taken about dashed box C shown in FIG. 3, showing different feature (e.g., region, sub-region, contact structure, routing structure, control logic devices) configurations within a portion of the microelectronic device 100, in accordance with some embodiments of the disclosure. For example, as described in further detail below, FIGS. 5 through 7 show different configurations, within a horizontal area of the dash box C depicted in FIG. 3, of some of the first routing structures 232, some of the first contact structures 242, some of the second routing structures 246, some of the second contact structures 252, some of the third routing structures 250, some of the fourth contact structures 350, some of the fourth routing structures 340, some of the SA devices 346, and some of the SWD devices 348 positioned within different regions and sub-regions of the microelectronic device 100. Such feature configurations may be employed to couple some of the memory cells 236 (FIG. 4) of the memory array structure 200 (FIG. 4) to some of the SA devices 346 and some of the SWD devices 348 of the control circuitry structure 300 (FIG. 4). For clarity and ease of understanding of the drawings and related description, not all features of the microelectronic device 100 depicted in one or more of FIGS. 1 through 4 are depicted in FIGS. 5 through 7. For example, some features of the microelectronic device 100 vertically overlying or vertically underlying other features of the microelectronic device 100 are not shown in one or more of FIGS. 5 through 7 so as to provide a clearer view of the other features.

Referring first to FIG. 5, SA devices 346 (e.g., even SA devices, odd SA devices) within the first SA sub-regions 310A of the first control circuitry region 302A and the third control circuitry region 302C of the control circuitry structure 300 (FIG. 4) may be coupled to some of the digit line structures 224 (FIG. 4) (e.g., even digit line structures, odd digit line structures) of the memory array structure 200 (FIG. 4) through a combination of some of the first routing structures 232, some of the first contact structures 242, and some of the second routing structures 246 within the horizontal area of the digit line contact region 304 and some other of the second routing structures 246, some of the third routing structures 250, some of the fourth contact structures 350, and some of the fourth routing structures 340 within horizontal areas of the first SA sub-regions 310A. As shown in FIG. 5, a group of the second routing structures 246 may be employed to horizontally route from a group of the first contact structures 242 within the horizontal area of the digit line contact region 304 to groups of the third routing structures 250 (and associated second contact structures 252 (FIG. 4)) within the horizontal areas of the first SA sub-regions 310A. For an individual SA device 346 (e.g., an odd SA device, or an even SA device) within an individual first SA sub-region 310A, a first combination of at least one second routing structure 246, at least one second contact structure 252 (FIG. 4), at least one third routing structure 250, at least one fourth contact structure 350, and at least one fourth routing structure 340 may route and be coupled to one end (in the Y-direction) of the SA device 346; and a second combination of at least one other second routing structure 246, at least one other second contact structure 252 (FIG. 4), at least one other third routing structure 250, at least one other fourth contact structure 350, and at least one other fourth routing structure 340 may route and be coupled to another, opposite end (in the Y-direction) of the SA device 316. It will be understood that the description of this paragraph also applies to first SA sub-regions 310A within other of the control circuitry regions 302 (FIG. 3), as well as second SA sub-regions 310B (FIG. 3) within the control circuitry regions 302 (FIG. 3).

In some embodiments, first routing and contact groups are coupled to a group of the digit lines structures 224 (FIG. 4) employed as so-called “base” digit line structures (e.g., true digit line structures); and second routing and contact groups are coupled to an additional group of the digit lines structures 224 (FIG. 4) employed as so-called “complementary” digit line structures (e.g., digit bar line structures); or vice versa. The first routing and contact groups may respectively include at least one first routing structure 232, at least one first contact structure 242, at least one second routing structure 246, at least one third routing structure 250, at least one second contact structure 252 (FIG. 4), and at least one fourth contact structure 350. The second routing and contact groups may respectively include at least one other first routing structure 232, at least one other first contact structure 242, at least one other second routing structure 246, at least one other third routing structure 250, at least one other second contact structure 252 (FIG. 4), and at least one other fourth contact structure 350. As a non-limiting example, if an individual first SA sub-region 310A includes odd SA devices 346, the first routing and contact groups may be coupled to a group of the digit lines structures 224 (FIG. 4) employed as odd base digit line structures; and the second routing and contact groups may be coupled to an additional group of the digit lines structures 224 (FIG. 4) employed as odd complementary digit line structures; or vice versa. As another non-limiting example, if an individual first SA sub-region 310A includes even SA devices 346, the first routing and contact groups may be coupled to a group of the digit lines structures 224 (FIG. 4) employed as so-called even base digit line structures; and the second routing and contact groups may be coupled to an additional group of the digit lines structures 224 (FIG. 4) employed as even complementary digit line structures; or vice versa.

Still referring to FIG. 5, SWD devices 348 (e.g., even SWD devices, odd SWD devices) within an arm section 314B of the second SWD sub-region 312B of the third control circuitry region 302C of the control circuitry structure 300 (FIG. 4) may be coupled to some of the word line structures 218 (FIG. 4) (e.g., even word line structures, odd word line structures) of the memory array structure 200 (FIG. 4) through a combination of some of the first routing structures 232, some of the first contact structures 242, and some of the second routing structures 246 within the horizontal area of the word line contact region 306; some other of the second routing structures 246 within a horizontal area of the first SA sub-region 310A; and yet some other of the second routing structures 246, some of the third routing structures 250, some of the fourth contact structures 350, and some of the fourth routing structures 340 within the horizontal area of the arm section 314B of the second SWD sub-region 312B. As shown in FIG. 5, for an individual SWD device 348 (e.g., an odd SWD device, or an even SWD device) within an individual arm section 314B of an individual second SWD sub-region 312B, a group of the second routing structures 246 may be employed to horizontally route from a first contact structure 242 within the horizontal area of the word line contact region 306, through the first SA sub-region 310A, and to a third routing structure 250 (and an associated second contact structure 252 (FIG. 4)) within the horizontal area of the arm section 314B of the second SWD sub-region 312B. It will be understood that the description of this paragraph also applies to second SWD sub-regions 312B within other of the control circuitry regions 302 (FIG. 3), as well as first SWD sub-regions 312A (FIG. 3) within the control circuitry regions 302 (FIG. 3).

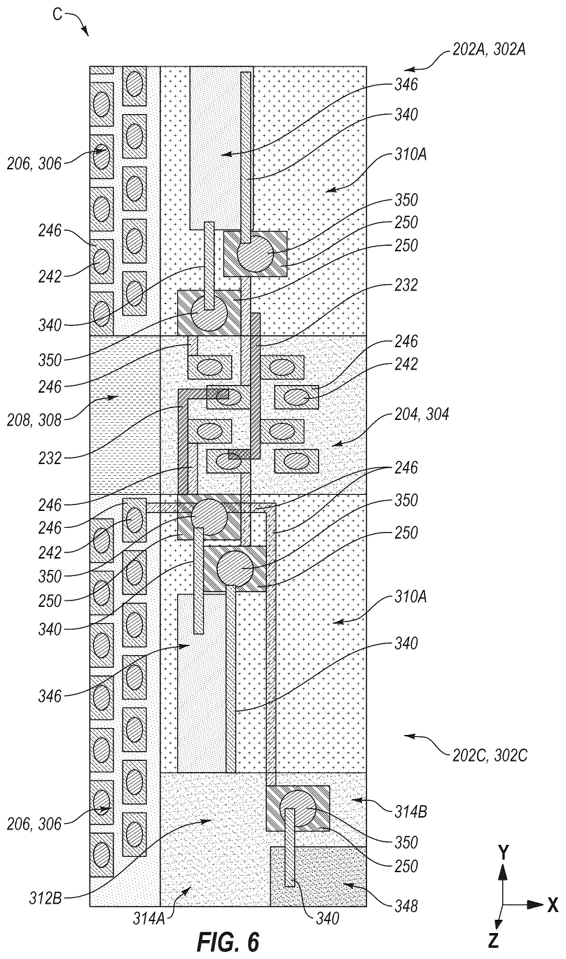

Referring next to FIG. 6, the depicted configuration may be similar to that previously described with reference to FIG. 5, except that for an individual SA device 346 (e.g., an odd SA device, or an even SA device) within an individual first SA sub-region 310A, both third routing structures 250 and both fourth contact structures 350 operatively associated with the SA device 346 are positioned at the same end (in the Y-direction) of the SA device 346 as one another. Both third routing structures 250 and both fourth contact structures 350 may be horizontally interposed, in the Y-direction, between the SA device 346 and the digit line contact region 304. A first combination of at least one second routing structure 246, at least one second contact structure 252 (FIG. 4), at least one third routing structure 250, at least one fourth contact structure 350, and at least one fourth routing structure 340 may route and be coupled to an end (in the Y-direction) of the SA device 346; and a second combination of at least one other second routing structure 246, at least one other second contact structure 252 (FIG. 4), at least one other third routing structure 250, at least one other fourth contact structure 350 may route to a position proximate the same end (in the Y-direction) of the SA device 346, and then at least one other fourth routing structure 340 may route from the other fourth contact structure 350 to a another, opposite end (in the Y-direction) of the SA device 316. It will be understood that the description of this paragraph also applies to first SA sub-regions 310A within other of the control circuitry regions 302 (FIG. 3), as well as second SA sub-regions 310B (FIG. 3) within the control circuitry regions 302 (FIG. 3).

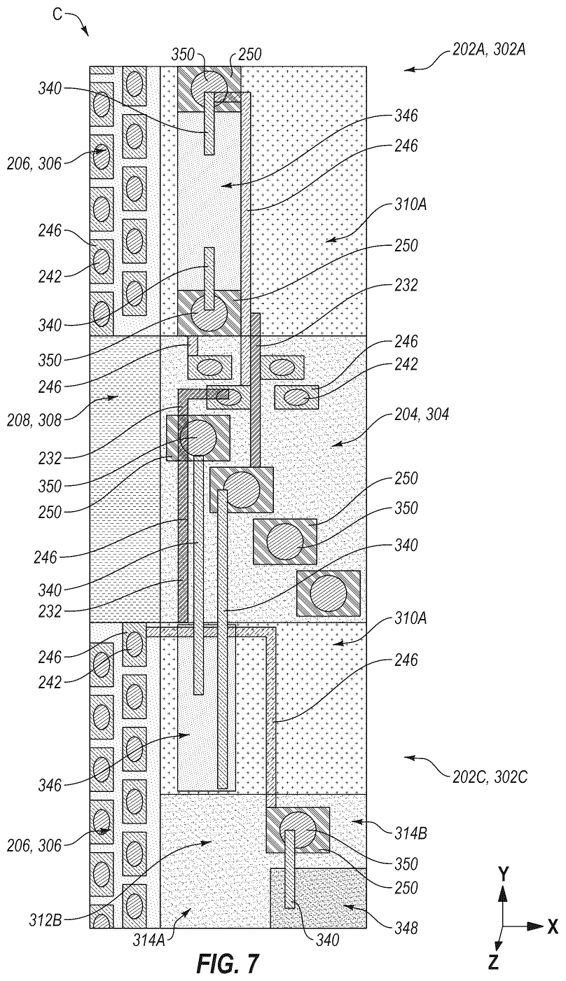

Referring next to FIG. 7, the depicted configuration may have some similarities to that previously described with reference to FIG. 5, but some third routing structures 250, some fourth contact structures 350, and portions of some fourth routing structure 340 operatively associated within some of the SA devices 346 may be positioned within the horizontal area of the digit line contact region 304 rather than within the horizontal area of the first SA sub-region 310A containing the some of the SA devices 346. As a non-limiting example, for an individual SA device 346 within the first SA sub-region 310A of the third control circuitry region 302C, the SA device 346 may be coupled to digit line structures 224 (FIG. 4) of the memory array structure 200 (FIG. 4) through a combination of some of the first routing structures 232, some of the first contact structures 242, some of the second routing structures 246, some of the third routing structures 250, and some of the fourth contact structures 350 within the horizontal area of the digit line contact region 304, as well as some of the fourth routing structures 340 horizontally extending from the fourth contact structures 350 to the SA device 346. As a result of including some of the third routing structures 250 and some of the fourth contact structures 350 within the digit line contact region 304, a horizontal dimension in the Y-direction of the digit line contact region 304 (and, hence, a horizontal dimension of the associated digit line exit region 204) may be relatively larger than a horizontal dimension in the Y-direction of the digit line contact region 304 for the configurations previously described herein with reference to FIGS. 5 and 6.

Thus, in accordance with embodiments of the disclosure, a microelectronic device includes a control circuitry structure and a memory array structure vertically underlying and bonded to the control circuitry structure. The control circuitry structure includes a control circuitry region. The control circuitry region includes two sense amplifier (SA) sub-regions including SA circuitry, and two sub-word line driver (SWD) sub-regions including SWD circuitry. The two SA sub-regions horizontally extend from and between opposing horizontal boundaries of the control circuitry region in a first direction. The two SWD sub-regions are horizontally interposed between the two SA sub-regions in a second direction orthogonal to the first direction and individually include a central region adjacent a respective one of the opposing horizontal boundaries of the control circuitry region, and two arm regions at opposing ends of the central region in the second direction and respectively horizontally protruding, in the first direction, from the central region toward a horizontal center of the control circuitry region. The memory array structure includes an array region horizontally overlapping the control circuitry region of the control circuitry structure and having memory cells within a horizontal area thereof.

Furthermore, in accordance with embodiments of the disclosure, a memory device includes a memory array structure and a control circuitry structure vertically overlying and attached to the memory array structure. The memory array structure includes array regions, digit line exit regions, and word line exit regions. The array regions include memory cells, digit lines, and word lines. The digit line exit regions horizontally alternate with the array regions in a first direction and include horizontal ends of the digit lines within horizontal areas thereof. The word line exit regions horizontally alternate with the array regions in a second direction orthogonal to the first direction and include horizontal ends of the word lines within horizontal areas thereof. The control circuitry structure includes control circuitry regions, digit line contact regions, and word line contact regions. The control circuitry regions horizontally overlap the array regions of the memory array structure and respectively include sense amplifier (SA) sub-regions individually including SA devices, and sub-word line driver (SWD) sub-regions individually including SWD devices. The SWD sub-regions are respectively horizontally interposed between the SA sub-regions in the first direction and individually include a central section and arm sections offset from one another in the first direction and each projecting from the central section the second direction. The digit line contact regions horizontally alternate with the control circuitry regions in the first direction and horizontally overlap the digit line exit regions of the memory array structure. The word line contact regions horizontally alternate with the control circuitry regions in the second direction and horizontally overlap the word line exit regions of the memory array structure.

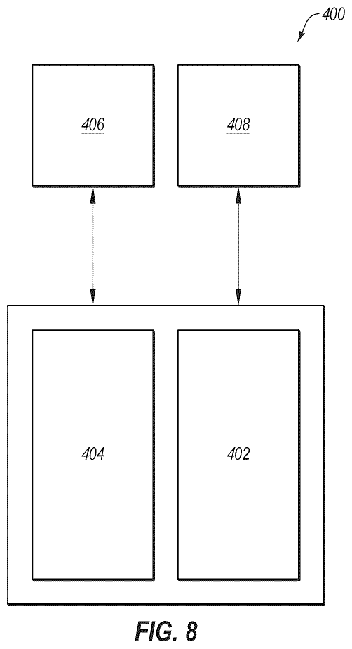

Microelectronic devices (e.g., the microelectronic device 100) in accordance with embodiments of the disclosure may be used in embodiments of electronic systems of the disclosure. For example, FIG. 8 is a block diagram illustrating an electronic system 400 according to embodiments of disclosure. The electronic system 400 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 400 includes at least one memory device 402. The memory device 402 may comprise, for example, a microelectronic device (e.g., the microelectronic device 100) previously described herein. The electronic system 400 may further include at least one electronic signal processor device 404 (often referred to as a “microprocessor”). The electronic signal processor device 404 may, optionally, comprise a microelectronic device (e.g., the microelectronic device 100) previously described herein. While the memory device 402 and the electronic signal processor device 404 are depicted as two (2) separate devices in FIG. 8, in additional embodiments, a single (e.g., only one) memory/processor device having the functionalities of the memory device 402 and the electronic signal processor device 404 is included in the electronic system 400. In such embodiments, the memory/processor device may include a microelectronic device (e.g., the microelectronic device 100) previously described herein. The electronic system 400 may further include one or more input devices 406 for inputting information into the electronic system 400 by a user, such as, for example, a mouse or other pointing device, a keyboard, a touchpad, a button, or a control panel. The electronic system 400 may further include one or more output devices 408 for outputting information (e.g., visual or audio output) to a user such as, for example, a monitor, a display, a printer, an audio output jack, a speaker, etc. In some embodiments, the input device 406 and the output device 408 comprise a single touchscreen device that can be used both to input information to the electronic system 400 and to output visual information to a user. The input device 406 and the output device 408 may communicate electrically with one or more of the memory device 402 and the electronic signal processor device 404.

Thus, in accordance with embodiments of the disclosure, an electronic system includes a processor device operably connected to an input device and an output device, and a memory device operably connected to the processor device. The memory device includes a memory array structure and a control circuitry structure vertically overlying and bonded to the memory array structure. The memory array structure includes an array region having dynamic random-access memory (DRAM) cells therein. The DRAM cells respectively include an access device and a capacitor vertically overlying and coupled to the access device. The control circuitry structure includes a control circuitry region horizontally overlapping the array region of the memory array structure. The control circuitry region includes a central section and a pair of arm sub-regions. The central section is at a horizontal boundary of the control circuitry region in a second direction orthogonal to the first direction and horizontally extends in the first direction. The pair of arm sub-regions project from the central section in the second direction toward a horizontal center of the control circuitry region in the second direction.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalent. For example, elements and features disclosed in relation to one embodiment may be combined with elements and features disclosed in relation to other embodiments of the disclosure.

What is claimed is:

1. A microelectronic device, comprising:
a control circuitry structure including a control circuitry region comprising:
two sense amplifier (SA) sub-regions comprising SA circuitry, the two SA sub-regions horizontally extending from and between opposing horizontal boundaries of the control circuitry region in a first direction; and
two sub-word line driver (SWD) sub-regions comprising SWD circuitry, the two SWD sub-regions horizontally interposed between the two SA sub-regions in a second direction orthogonal to the first direction and individually including:
a central region adjacent a respective one of the opposing horizontal boundaries of the control circuitry region; and
two arm regions at opposing ends of the central region in the second direction and respectively horizontally protruding, in the first direction, from the central region toward a horizontal center of the control circuitry region; and
a memory array structure vertically underlying and bonded to the control circuitry structure, the memory array structure comprising an array region horizontally overlapping the control circuitry region of the control circuitry structure and having memory cells within a horizontal area thereof.

2. The microelectronic device of claim 1, wherein the two SWD sub-regions comprise:
an odd SWD sub-region comprising odd SWD devices coupled to odd word lines extending through the array region of the memory array structure in the first direction, the odd word lines coupled to odd rows of the memory cells; and
an even SWD sub-region opposing the odd SWD sub-region in the first direction and comprising even SWD devices coupled to even word lines extending through the array region of the memory array structure in the first direction, the even word lines coupled to even rows of the memory cells.

3. The microelectronic device of claim 2, wherein the two SA sub-regions comprise:
an odd SA sub-region comprising odd SA devices coupled to odd digit lines extending through the array region of the memory array structure in the second direction, the odd digit lines coupled to odd columns of the memory cells; and
an even SA sub-region opposing the odd SA sub-region in the second direction and comprising even SA devices coupled to even digit lines extending through the array region of the memory array structure in the second direction, the even digit lines coupled to even columns of the memory cells.

4. The microelectronic device of claim 1, wherein:
the control circuitry structure further comprises:
two word line contact regions flanking the opposing horizontal boundaries of the control circuitry region in the first direction; and
two digit line contact regions flanking additional opposing horizontal boundaries of the control circuitry region in the second direction; and
the memory array structure further comprises:
two word line exit regions flanking opposing horizontal boundaries of the array region in the first direction, the two word line exit regions horizontally overlapping the two word line contact regions of the control circuitry structure; and
two digit line exit regions flanking additional opposing horizontal boundaries of the array region in the second direction, the two digit line exit regions horizontally overlapping the two digit line contact regions of the control circuitry structure.

5. The microelectronic device of claim 4, further comprising first arrangements of conductive structures coupled to the memory cells within the array region of the memory array structure and the SA circuitry within the two SA sub-regions of the control circuitry region of the control circuitry structure, the first arrangements of conductive structures extending through the two digit line exit regions of the memory array structure and the two digit line contact regions of the control circuitry structure.

6. The microelectronic device of claim 5, wherein the first arrangements of conductive structures comprise:
first contact structures within the memory array structure and vertically overlying and coupled to digit lines coupled to the memory cells within the array region of the memory array structure;
first routing structures within the memory array structure and vertically overlying and coupled to the first contact structures;
second contact structures within the memory array structure and vertically overlying and coupled to the first routing structures;
second routing structures within the memory array structure and vertically overlying and coupled to the second contact structures;
third contact structures within the memory array structure and vertically overlying and coupled to the second routing structures;
third routing structures within the memory array structure and vertically overlying and coupled to the third contact structures;
fourth contact structures partially extending through each of control circuitry structure and the memory array structure, the fourth contact structures vertically overlying and coupled to the third routing structures; and
fourth routing structures within the control circuitry structure and vertically overlying and coupled to the fourth contact structures.

7. The microelectronic device of claim 6, wherein:
the first contact structures, the first routing structures, the second contact structures, and some of the second routing structures are positioned within horizonal areas of the two digit line exit regions of the memory array structure and the two digit line contact regions of the control circuitry structure; and
some others of the second routing structures, the third contact structures, the third routing structures, the fourth contact structures, and the fourth routing structures are positioned within horizonal areas of the two SA sub-regions of the control circuitry region of the control circuitry structure.

8. The microelectronic device of claim 6, wherein:
the first contact structures, the first routing structures, the second contact structures, some of the second routing structures, some of the third contact structures, some of the third routing structures, some of the fourth contact structures, and some of the fourth routing structures are positioned with horizonal areas of the two digit line exit regions of the memory array structure and the two digit line contact regions of the control circuitry structure; and
some others of the second routing structures, some others of the third contact structures, some others of the third routing structures, some others of the fourth contact structures, and some others of the fourth routing structures are positioned within horizonal areas of the two SA sub-regions of the control circuitry region of the control circuitry structure.

9. The microelectronic device of claim 6, further comprising second arrangements of conductive structures coupled to the memory cells within the array region of the memory array structure and the SWD circuitry within the two SWD sub-regions of the control circuitry region of the control circuitry structure, the second arrangements of conductive structures extending through the two word line exit regions of the memory array structure and the two word line contact regions of the control circuitry structure.

10. A memory device, comprising:
a memory array structure comprising:
array regions comprising memory cells, digit lines, and word lines;
digit line exit regions horizontally alternating with the array regions in a first direction and comprising horizontal ends of the digit lines within horizontal areas thereof; and
word line exit regions horizontally alternating with the array regions in a second direction orthogonal to the first direction and comprising horizontal ends of the word lines within horizontal areas thereof;
a control circuitry structure vertically overlying and attached to the memory array structure, the control circuitry structure comprising:
control circuitry regions horizontally overlapping the array regions of the memory array structure and respectively comprising:
sense amplifier (SA) sub-regions individually comprising SA devices; and
sub-word line driver (SWD) sub-regions individually comprising SWD devices, the SWD sub-regions respectively horizontally interposed between the SA sub-regions in the first direction and individually comprising:
a central section; and
arm sections offset from one another in the first direction and each projecting from the central section the second direction;
digit line contact regions horizontally alternating with the control circuitry regions in the first direction and horizontally overlapping the digit line exit regions of the memory array structure; and
word line contact regions horizontally alternating with the control circuitry regions in the second direction and horizontally overlapping the word line exit regions of the memory array structure.

11. The memory device of claim 10, wherein, for respective ones of the control circuitry regions, each of the SWD sub-regions thereof horizontally extends in the first direction from one of the SA sub-regions thereof to an additional one of the SA sub-regions thereof.

12. The memory device of claim 11, wherein, for the respective ones of the control circuitry regions, the arm sections of each of the SWD sub-regions thereof respectively comprise:
a first arm region directly adjacent the one of the SA sub-regions in the first direction; and
a second arm region directly adjacent the additional one of the SA sub-regions in the first direction.

13. The memory device of claim 10, further comprising routing tiers comprising:
a first routing tier within the memory array structure and comprising first routing structures coupled to the memory cells within the array regions;
a second routing tier within the memory array structure and vertically overlying the memory cells, the second routing tier comprising second routing structures coupled to the first routing structures of the first routing tier;
a third routing tier within the memory array structure and vertically overlying the second routing tier, the third routing tier comprising third routing structures coupled to the second routing structures of the second routing tier; and
a fourth routing tier within the control circuitry structure and comprising fourth routing structures coupled to the third routing structures of the third routing tier.

14. The memory device of claim 13, further comprising:
first contact structures within the digit line exit regions of the memory array structure and vertically extending from some of the first routing structures of the first routing tier to the horizontal ends of the digit lines;
second contact structures within the digit line exit regions of the memory array structure and vertically extending from some of the second routing structures of the second routing tier to the some of the first routing structures of the first routing tier;
third contact structures within the memory array structure and vertically extending from some of the third routing structures of the third routing tier to the some of the second routing structures of the second routing tier; and
fourth contact structures vertically extending from some of the fourth routing structures of the fourth routing tier to the some of the third routing structures of the third routing tier, the some of the fourth routing structures coupled to the SA devices within the SA sub-regions of the control circuitry regions of the control circuitry structure.

15. The memory device of claim 14, wherein the third contact structures, the fourth contact structures, and the some of the fourth routing structures are respectively positioned within horizontal areas of the SA sub-regions of the control circuitry regions of the control circuitry structure.

16. The memory device of claim 14, further comprising:
first additional contact structures within the word line exit regions of the memory array structure and vertically extending from some others of the first routing structures of the first routing tier to the horizontal ends of the word lines;
second additional contact structures within the word line exit regions of the memory array structure and vertically extending from some others of the second routing structures of the second routing tier to the some others of the first routing structures of the first routing tier;
third additional contact structures within the memory array structure and vertically extending from some others of the third routing structures of the third routing tier to the some others of the second routing structures of the second routing tier; and
fourth additional contact structures vertically extending from some others of the fourth routing structures of the fourth routing tier to the some others of the third routing structures of the third routing tier, the some others of the fourth routing structures coupled to the SWD devices within the SWD sub-regions of the control circuitry regions of the control circuitry structure.

17. The memory device of claim 16, wherein the third additional contact structures, the fourth additional contact structures, and the some others of the fourth routing structures are respectively positioned within horizontal areas of the SWD sub-regions of the control circuitry regions of the control circuitry structure.

18. An electronic system, comprising:
a processor device operably connected to an input device and an output device; and
a memory device operably connected to the processor device and comprising:
a memory array structure including an array region having dynamic random-access memory (DRAM) cells therein, the DRAM cells respectively comprising an access device and a capacitor vertically overlying and coupled to the access device; and
a control circuitry structure vertically overlying and bonded to the memory array structure, the control circuitry structure comprising a control circuitry region horizontally overlapping the array region of the memory array structure and comprising:
sense amplifier (SA) sub-regions comprising SA devices coupled to the DRAM cells within the array region of the memory array structure; and
sub-word line driver (SWD) sub-regions comprising SWD devices coupled to the DRAM cells within the array region of the memory array structure, the SWD sub-regions horizontally extending from and between the SA sub-regions in a first direction and respectively comprising:
a central section at a horizontal boundary of the control circuitry region in a second direction orthogonal to the first direction and horizontally extending in the first direction; and
a pair of arm sub-regions projecting from the central section in the second direction toward a horizontal center of the control circuitry region in the second direction.

19. The electronic system of claim 18, wherein the SA sub-regions and the SWD sub-regions are confined within a horizontal area of the control circuitry region of the control circuitry structure.

20. The electronic system of claim 18, wherein channels of transistors of the SA devices and the SWD devices of the control circuitry structure are positioned vertically closer to the DRAM cells of the memory array structure than are gate electrodes of the channels of transistors of the SA devices and the SWD devices of the control circuitry structure.
